(19) United States
(12) Patent Application Publication
(10) Pub. No.: US 2014/0174533 A1
(43) Pub. Date: Jun. 26, 2014

(54) SOLAR MODULE WITH LIGHT-TRANSMISSIVE EDGE SEAL

(71) Applicant: First Solar, Inc., Perrysburg, OH (US)

(72) Inventors: Benyamin Buller, Sylvania, OH (US); Stephen P. Murphy, Perrysburg, OH (US); Brian E. Cohen, Perrysburg, OH (US)

(73) Assignee: First Solar, Inc., Perrysburg, OH (US)

(21) Appl. No.: 14/102,879

(22) Filed: Dec. 11, 2013

Related U.S. Application Data
(63) Continuation of application No. 12/874,817, filed on Sep. 2, 2010, now abandoned.

(51) Int. Cl. H01L 31/048

(52) U.S. Cl. CPC H01L 31/048
USPC 136/259

(57) ABSTRACT

A solar module with a front support, a back support, and a photovoltaic active material located between the front and back supports. An electrically insulative light transmissive seal is located at the peripheral edges of the front support and back support to electrically isolate the active material from the outer surfaces of the solar module.

### FIELD OF THE INVENTION

This application is a continuation of U.S. application Ser. No. 12/874,817, filed on Sep. 2, 2010, the entire disclosure of which is incorporated herein by reference.

Embodiments of the invention relate to the field of photovoltaic (PV) power generation systems, and more particularly to a solar module and a manufacturing method thereof.

### BACKGROUND OF THE INVENTION

A photovoltaic module or solar module, also known as a solar panel, is a device that converts the energy of sunlight directly into electricity by the photovoltaic effect. A solar module includes a plurality of photovoltaic cells, also known as solar cells, for example, crystalline silicon cells or thin-film cells. The photovoltaic cells convert light into electrical energy and are typically formed between front and back supports of the solar module. In thin-film modules, the photovoltaic cell can include sequential layers of various materials formed between the front support and the back support. Layers can include, for example, a barrier layer, a transparent conducting oxide (TCO) layer, a buffer layer, and an active material layer, all which can be deposited on top of the back support. The active material layer is formed of one or more layers of semiconductor material such as amorphous silicon (a-Si), copper indium gallium diselenide (CIGS), cadmium telluride (CdTe), cadium sulfide (CdS) or any other suitable light absorbing material.

The front and back supports provide structural support and protect the solar cells from environmental hazards. The front and back supports of a solar module are made of a transparent material, for example, glass, to allow light to pass through to the active material layer. As light passes through the front and back supports and strikes the active material, the active material generates electricity. As a result, solar modules may be dangerous when being installed and handled since exposing the module to light causes the module to generate electricity. Thus, solar modules are equipped with safety features to reduce the risk of electric shock during installation, operation, and service of the modules.

The growing demand for solar power pushes for advancements in solar modules which will produce higher energy yields for a given module footprint. At the same time, as demand to produce highly efficient solar modules grows, the safety features of solar modules should not be compromised. Accordingly, a solar module with improved energy output without compromising its safety characteristics is desirable.

### BRIEF DESCRIPTION OF THE DRAWINGS

FIG. 1a is a cross-sectional view of one embodiment of a solar module;

FIG. 1b is a partial cross-sectional view of another embodiment of a solar module;

FIG. 2 is a cross-sectional view of another embodiment of a solar module;

FIG. 3 is a top view of a solar module of FIG. 2;

FIG. 4 is a cross-sectional view of another embodiment of a solar module;

FIG. 5 is a cross-sectional view of another embodiment of a solar module;

FIG. 6 is a cross-sectional view of another embodiment of a solar module;

FIG. 7 is a cross-sectional view of another embodiment of a solar module;

FIG. 8 is a cross-sectional view of another embodiment of a solar module;

FIG. 9 is cross-sectional view of a mold used to form an insulating seal around the periphery of a solar module; and

FIG. 10 is perspective view of one embodiment of an insulating seal that may be attached to the periphery of a solar module.

### DETAILED DESCRIPTION OF THE INVENTION

In the following detailed description, reference is made to the accompanying drawings which form a part hereof, and in which is shown by way of illustration specific embodiments that may be practiced. These embodiments are described in sufficient detail to enable those skilled in the art to make and use them, and it is to be understood that structural, logical, or procedural changes may be made to the specific embodiments disclosed without departing from the spirit and scope of the invention.

Electrical output from a solar module typically depends on the surface area of the active material available for active light collection. Increasing the surface area of the active material without increasing the module footprint increases the energy output rating of the module. That said, to reduce the risk of electrical shock, a minimum distance, called the “tracking distance,” between the active material and an exposed outer surface of the module needs to be maintained. U.S. Patent Application Ser. No. 61/122,571 and Ser. No. 12/636,689 describe the design of a solar module that reduces the risk of electric shock by maintaining a suitable tracking distance. These applications describe that a suitable tracking distance is maintained by encapsulating the peripheral edge of the module with an electrical insulator. Described herein, however, are embodiments of a solar module design that can provide a sufficient tracking distance and an increased energy output rating for the module when compared to prior art implementations of the solar module.

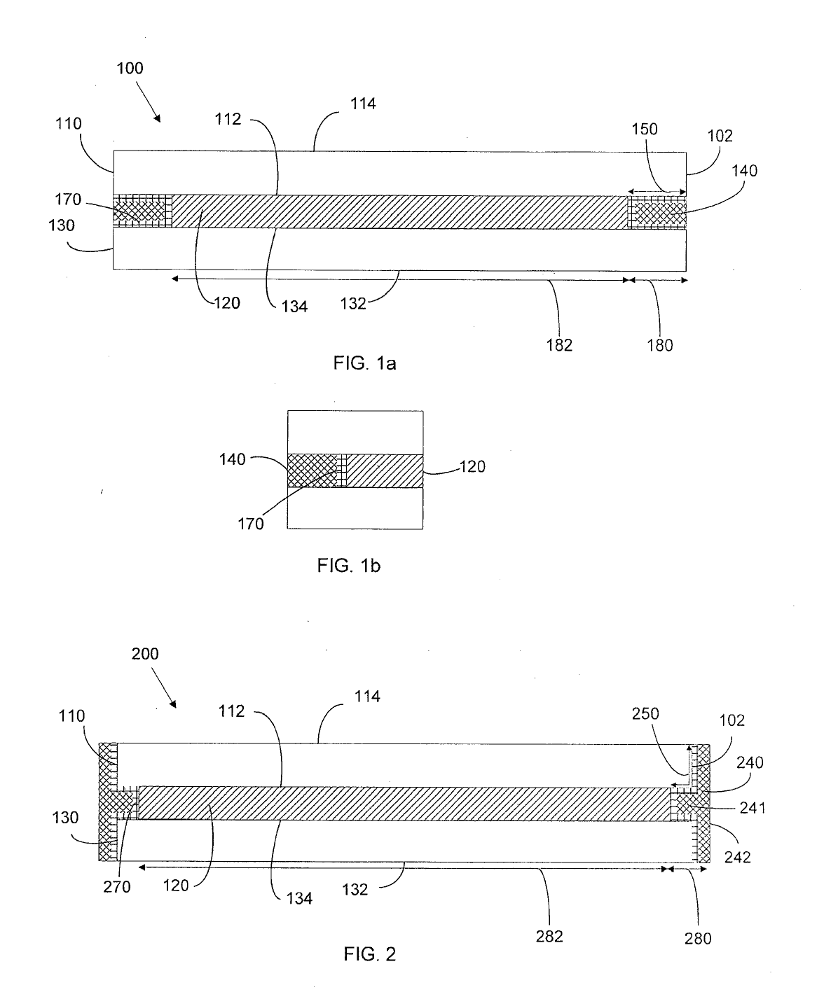

A first embodiment of a solar module 100 is depicted in FIG. 1a. It should be noted that solar module 100 is not intended to be considered a limitation on the types of solar modules to which the present invention may be applied, but rather a convenient representation for the following description. For example, solar module 100 may be representative of any type of thin-film or other solar module.

Solar module 100 includes a front support 110 and a back support 130, both of which are made of an insulative material that is transparent or translucent to light, for example, glass. Front support 110 has a width, length, front surface 114, and back surface 112. Back support 130 has a width, length, front surface 134, and back surface 132. The width and length of front support 110 is substantially the same as the width and length of back support 130. Front support 110 and back support 130 are aligned to define peripheral edge 102 of front and back supports 110, 130.

Solar module 100 further includes an active photosensitive material 120 located between front support 110 and back support 130. In this embodiment, active photo sensitive material 120 has a width and length and is positioned between front support 110 and back support 130 and arranged so that a suitable tracking distance is maintained between all edges of active material 120 and peripheral edge 102. Maintaining the suitable tracking distance creates, in this embodiment, an inactive area 180 between all edges of active material 120 and peripheral edge 102. Inactive area 180 is defined as the area of solar module 100 that does not convert incident light to electrical energy. The remaining portion of solar module 100 is an active area 182 that enables incident light to generate electricity.

Solar module 100 also includes an electrically insulating seal 140. Insulating seal 140 is provided between front support 110 and back support 130 between the edge of active material 120 and peripheral edge 102. Insulating seal 140 may be light transmissive and formed of a polymer material that is selected from a group consisting of polycarbonate, acrylic, silicone, and polyurethane. Further, insulating seal 140 may be of a UV stable type polymer or any other insulative material. In another embodiment, light transmissive insulating seal 140 may also be transparent or translucent. Since insulating seal 140 is made of light transmissive material, light striking solar module 100 at peripheral edge 102 may strike active material 120 and be converted into electricity.

In another embodiment, module 100 may further include material 170 provided as a layer between insulating seal 140 and active material 120, front support 110, and back support 130. Material 170 may be light transmissive and may also be transparent or translucent. Material 170 may be a moisture barrier that comprises a desiccant loaded ultra-low water vapor transport rate polymer such as polyisobutylene or some other type of moisture barrier polymer or material. Material 170 may also be or include a primer formed from one of a variety of resins or an adhesive such as organosilane or titanate. The type of adhesive used may depend on the composition of insulating seal 140.

Although FIG. 1 a shows material 170 as located between insulating seal 140 and active material 120, front support 110, and back support 130, it could also be located only between insulating seal 140 and active material 120 as shown in FIG. lb.

Even though active material 120 is surrounded by insulative material, an electrical current generated by active material 120 could discharge upon contact with the peripheral edge 102 of module 100. To discharge, the current would not pass through the surrounding insulative material but would follow a surface tracking path along a surface of the insulative materials. A surface tracking path within solar module 100 would be any path along a surface of an insulative material, such as either the front or back supports 110, 130, or insulating seal 140, that an electrical current from active material 120 could travel along to reach a point on an outer surface of module 100 that could discharge upon contact. For example, FIG. 1a illustrates one of many possible surface tracking paths, surface tracking path 150. Surface tracking path 150 starts at active material 120 travels along backsurface 112 of front support 110 to peripheral edge 102.

While electrical current will travel along surface tracking paths in a solar module, it usually only travels a limited distance, which can be determined based on the voltage and other characteristics of the solar module. Thus, to reduce the occurrence of electrical discharge along a surface tracking path, the path needs to be longer than the distance the electricity typically travels. In this embodiment, the surface tracking distance along surface tracking path 150 may be at least 2 mm and within the range of between 2 mm to 50 mm. In one embodiment, the tracking distance for the FIG. 1 a embodiment may be about 10 mm.

Maintaining a prescribed tracking distance between peripheral edge 102 and active material 120 provides for reduced occurrences of electrical discharge because the tracking distance and insulating seal 140 in module 100 provide electrical isolation of active material 120 with respect to the outer surface of module 100 and areas outside module 100. That said, maintaining a prescribed tracking distance also results in inactive area 180 of solar module 100 since active material 120 does not extend to peripheral edge 102. Further, in module 100, the tracking distance is dependent on the size of active area 182 and inactive area 180. For example, in the FIG. 1a embodiment if the tracking distance is increased the size of active area 182 decreases and the size of inactive area 180 increases.

Another embodiment of a solar module 200 is depicted in FIG. 2. In this embodiment, active material 120 extends closer to peripheral edge 102 than active material 120 in solar module 100 but does not extend all the way to peripheral edge 102.

Further, as shown in FIG. 2, an insulating seal 240 including a sidewall 242 that extends across peripheral edge 102 of solar module 200. Sidewall 242 may cover the entire peripheral edge 102 of solar module 100 by extending to the front surface 114 of front support 110 and to the back surface 132 of back support 130. Also, insulating seal 240 includes an extension 241 that extends between front support 110 and back support 130 away from peripheral edges 102 toward active material 120. Extension 241 of insulating seal 240 may also contact active material 120 without material 170 there between. Together, sidewall 242 and extension 241 of insulative seal 240 form a T-shaped member that provides electrical isolation of active material 120 with respect to areas outside solar module 200.

In module 200, inactive area 280 extends from the edge of active material 120 to the outer edge of sidewall 242, since light incident to this area will not strike active material 120 and generate electricity. The remaining portions of module 200 comprise active area 282. Further, in module 200, a depicted tracking path 250 extends from active material 120 along back surface 112 of front support 110 and along a portion of peripheral edge 102 to front surface 114 of front support 110. Since a portion of tracking path 250 extends along peripheral edge 102, this allows active material 120 to extend closer to peripheral edge 102 while still maintaining a prescribed tracking distance.

With active material 120 extending closer to peripheral edge 102, the surface area of active material 120 is increased and the active area 282 is increased without increasing the footprint of module 200. As a result, module 200 has an increased electrical output as compared to module 100. That said, any tracking distance in module 200 is still dependent on the size of inactive and active areas 280, 282 because it may not be further increased without adjusting the size of the inactive and active areas 280, 282.

In module 200, tracking path 250 may have a tracking distance of at least 2 mm and may be between 2 mm to 50 mm with about 10 mm being a good choice.

In another embodiment, insulating seal 240 is light transmissive and may be formed of a polymer material that can include, but is not limited to, such as polycarbonate, acrylic, silicone, and polyurethane. Additionally, insulating seal 240 may be of a UV stable type polymer or any other light transmissive insulative material. In another embodiment, insulating seal 240 may be formed of an insulative material that allows the transmission of wavelengths of light generated by the sun to reach the active material 120 (e.g., a transparent or translucent material).

Module 200 may further include material 270 provided as a layer between insulating seal 240 and active material 120, front support 110, and back support 130. Material 270 may be light transmissive and may also be transparent or translucent. Material 270 may be a moisture barrier that comprises a desiccant loaded ultra-low water vapor transport rate polymer such as polyisobutylene or some other type of moisture barrier polymer or material. Material 270 may also be or include a primer formed from one of a variety of resins or an adhesive such as organosilane or titanate. The type of adhesive used may depend on the composition of insulating seal 240.

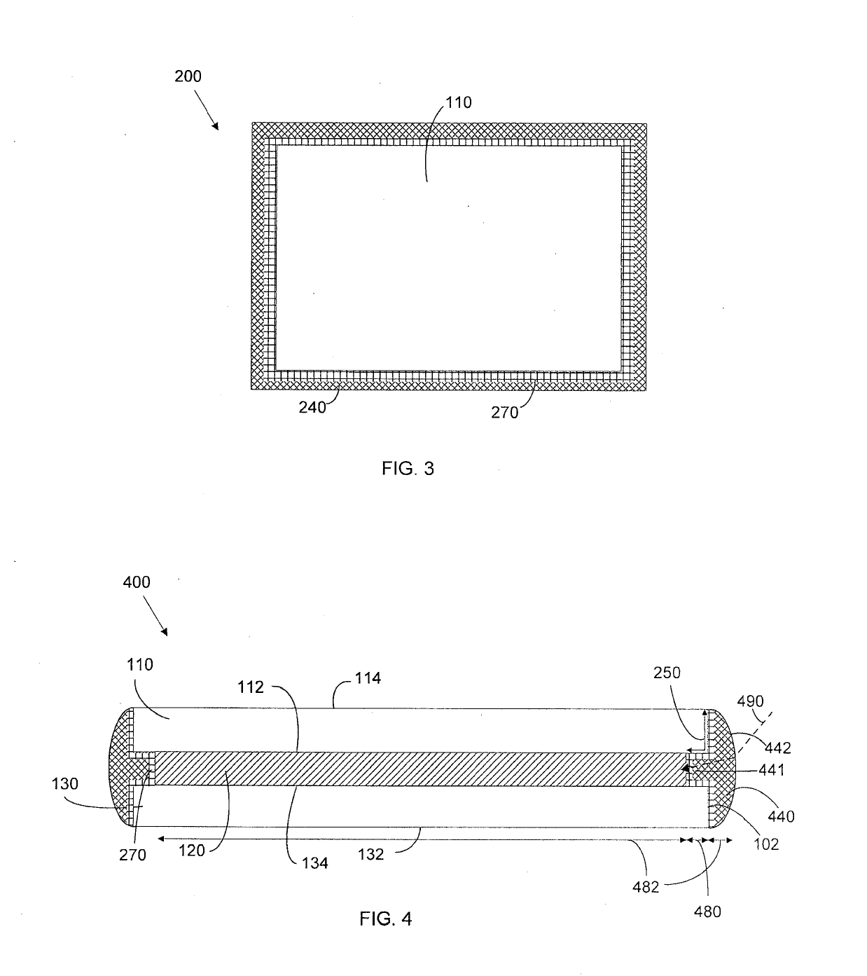

A top view of module 200 is illustrated in FIG. 3. As shown in FIGS. 2 and 3, insulating seal 240 and material 270 extend completely around the periphery of front support 110 and back support 130.

In another embodiment shown in FIG. 4, a sidewall 442 of insulating seal 440 extends across peripheral edge 102 of solar module 400 and has a rounded outer surface. Also, an extension 441 of insulating seal 440 extends between front support 110 and back support 130 away from peripheral edge 102 toward active material 120. Insulating seal 440 is formed of a light transmissive insulative material that is allows wavelengths of light generated by the sun to reach the active material 120 (e.g., a transparent or translucent material). Module 400 may further include material 270 provided as a layer between insulating seal 440 and active material 120, front support 110, and back support 130.

In this embodiment, the curved exterior surface of sidewall 442 acts as a lens to redirect incident light 490 contacting sidewall 442 to active material 120 thereby further increasing the efficiency of module 400. Thus, sidewall 442 can be considered as a part of active area 482 of module 400, because light incident to sidewall 442 is redirected to active material 120 and converted to electricity. Active area 482 also includes the area of module 400 that is encompassed by active material 120. As a result, inactive area 480 of module 400 is smaller than inactive area 280 of module 200.

In module 400, depicted tracking path 250 extends from active material 120 along backside back surface 112 of front support 110 and along a portion of peripheral edge 102 to front surface 114 of front support 110. Since a portion of tracking path 250 extends along peripheral edge 102, active material 120 may extend closer to peripheral edge 102 and still maintain a prescribed tracking distance. Further, with active material 120 extending closer to peripheral edge 102, the surface area of active material 120 is increased without increasing the footprint of module 400. As a result, module 400 has increased electrical output as compared to module 100 and module 200. That said, any tracking distance in module 400 is still dependent on the size of active and inactive areas 480, 482 because it may not be further increased without adjusting the size of active and inactive areas 480, 482.

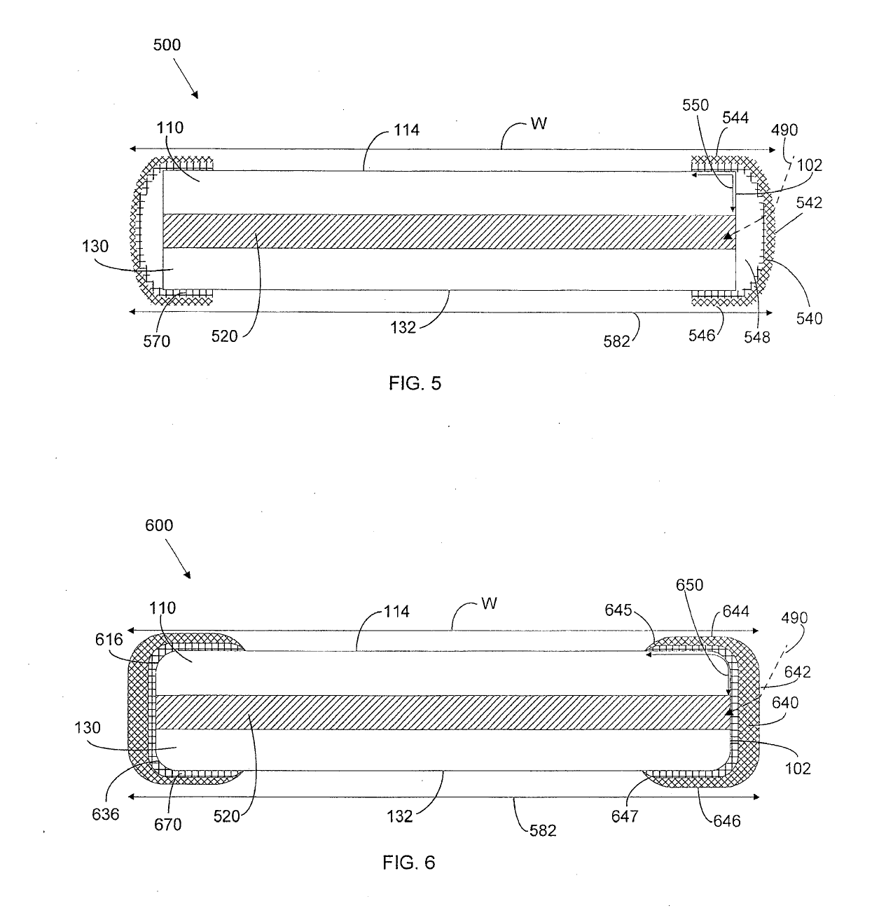

FIG. 5 illustrates another embodiment of a solar module 500. Active material 520 has a width and length that is substantially similar to the width and length of front support 110 and back support 130. Thus, in solar module 500, active material 520 extends to peripheral edge 102 of module 500 thereby covering substantially the entire surface of front and back supports 110, 130 of solar module 500. In other embodiments, active material 520 may not totally reach peripheral edge 102 of module 500, but may extend to a range of within 2 cm to 0 mm of peripheral edge 102.

In order to increase the tracking distance for module 500, insulating seal 540 has a front edge 544 that extends across front surface 114 of front support 110 and a back edge 546 that extends across back surface 132 of back support 130. Insulating seal 540 is formed of an insulative material that is light transmissive and may be transparent or translucent to wavelengths of light generated by the sun. Since insulating seal 540 is transmissive to light, edges 544, 546 of insulating seal 540 do not block light to active material 520.

Insulating seal 540 further includes a sidewall 542 that extends between front and back edges 544, 546 thereby forming a C cross section shaped member. Incident light 490 in this embodiment contacts insulating seal 540 with an initial trajectory to pass through insulating seal 540 and not contact active material 520. However, the curved exterior surface of insulating seal 540 acts as a lens to redirect incident light 490 contacting insulating seal 540 to active material 520 thereby further increasing the efficiency of module 500. Thus, active area 582 extends along the entire width (W) of module 500 because active material 520 covers substantially the entire surface of solar module 500 and all light incident to sidewall 542 is redirected to active material 520. This can result in an approximate 5-7% active area increase for module 500 compared to module 100.

As before, insulating seal 540 provides a tracking path 550 that extends along peripheral edge 102 of front support 110 and now across the portion of front surface 114 of front support 110 that is covered by front edge 544 of insulating seal 540. A similar tracking path is provided across a portion of the back surface 132 of back support 130 over which back edge 546 extends as well as along the peripheral edge 102 of back support 130. Tracking distance of tracking path 550 is sufficient to provide for reduced possibility of electrical discharge while still allowing for a larger area for active material 520. Furthermore, any tracking distance in module 500 is independent of the size of active area 582 because it can be increased by increasing only the length of front and back edges 544, 546.

In this embodiment, the sidewall of insulating seal 540 is not in contact with peripheral edge 102 of module 500 thereby creating a sealed cavity 548 between sidewall 542 and peripheral edge 102. In another embodiment, portions of the sidewall of insulating seal 540 may contact peripheral edge 102 of module 500, while still creating cavity 548.

Cavity 548 may be empty space, but may be also filled with any suitable material. The material within cavity 548 may include a gas, for example, air or other gases, an adhesive and/or primer, silicone, a moisture barrier, such as polyisobutylene, or any type of insulative material. Further, cavity 548 may be filled with a material that is light transmissive such as one that is translucent or transparent.

Module 500 may further include a material 570 provided between insulating seal 540 and front and back supports 110, 130 and along the interior wall of sidewall 542. Material 570 may be light transmissive and may also be transparent or translucent. Material 570 may be a moisture barrier that comprises a desiccant loaded ultra-low water vapor transport rate polymer such as polyisobutylene or some other type of moisture barrier polymer or material. Material 570 may also be or include a primer formed from one of a variety of resins or an adhesive such as organosilane or titanate. The type of adhesive used may depend on the composition of insulating seal 540.

Solar module 600, shown in FIG. 6 illustrates another embodiment. Active material 520 has a width and length that is substantially similar to the width and length of front support 110 and back support 130. Thus, in solar module 600, active material 520 extends to peripheral edge 102 of module 600, thereby covering substantially the entire surface of front and back supports 110, 130 of solar module 600. In other embodiments, active material 520 may not reach peripheral edge 102 of module 600, but may extend to a range of 2 cm to 0 mm of peripheral edge 102.

Insulating seal 640 has a front edge 644 that extends across front surface 114 of front support 110 and a back edge 646 that extends across back surface 132 of back support 130. Insulating seal 640 is formed of an insulative material that is light transmissive and may be transparent or translucent. Since insulating seal 640 is light transmissive, edges 644 and 646 of insulating seal 640 that extend across front surface 114 of front support 110 and back surface of back supports 130 do not block light to active material 520.

Front edge 644 also includes a rounded end 645 and back edge 646 includes a rounded end 647. Further, a front corner 616 formed by the intersection of peripheral edge 102 and front support 110 has an upwardly rounded profile. A back corner 636 formed by the intersection of peripheral edge 102 and back support 130 has a downwardly rounded profile. Rounded corners 616, 636, and rounded ends 645, 647 act as lens to redirect incident light 490 toward active material 520 that would otherwise not reach active material 520.

Insulating seal 640 further includes a sidewall 642 that contacts the entire peripheral edge 102 of module 600 and extends between edges 644, 646 of insulating seal thereby forming an integral C shaped member. Incident light 490 in this embodiment contacts insulating seal 640 with an initial trajectory to pass through insulating seal 640 and not contact active material 520. However, the curved exterior surface of insulating seal 640 acts as a lens to redirect incident light 490 contacting insulating seal 640 to active material 520 thereby further increasing the efficiency of module 600. Thus, active area 582 extends along the entire width (w) of module 600 because all light incident to the surface of solar module 600 is directed to active material 520 and all light incident to sidewall 642 is redirected to active material 620. This can result in an approximate 5-7% active area increase for module 600 compared to module 100.

As before, insulating seal 640 provides tracking paths in module 600. One illustrated tracking path, tracking path 650, is shown extending along peripheral edge 102 of front support 110 and across the portion of front surface 114 of front support 110 that is covered by front edge 644 of insulating seal 640. The tracking distance of tracking path 650 provides for reduced possibility of electrical discharge. Furthermore, any tracking distance in module 600 is independent of the size of active area 582 because it can be increased by increasing only the length of front and back edges 644, 646.

Module 600 may further include a material 670 provided as a layer between insulating seal 640 and front and back supports 110, 130. Material 670 may be light transmissive and may also be transparent or translucent. Material 670 may be a moisture barrier that comprises a desiccant loaded ultra-low water vapor transport rate polymer such as polyisobutylene or some other type of moisture barrier polymer or material. Material 670 may also be or include a primer formed from one of a variety of resins or an adhesive such as organosilane or titanate. The type of adhesive used may depend on the composition of insulating seal 640.

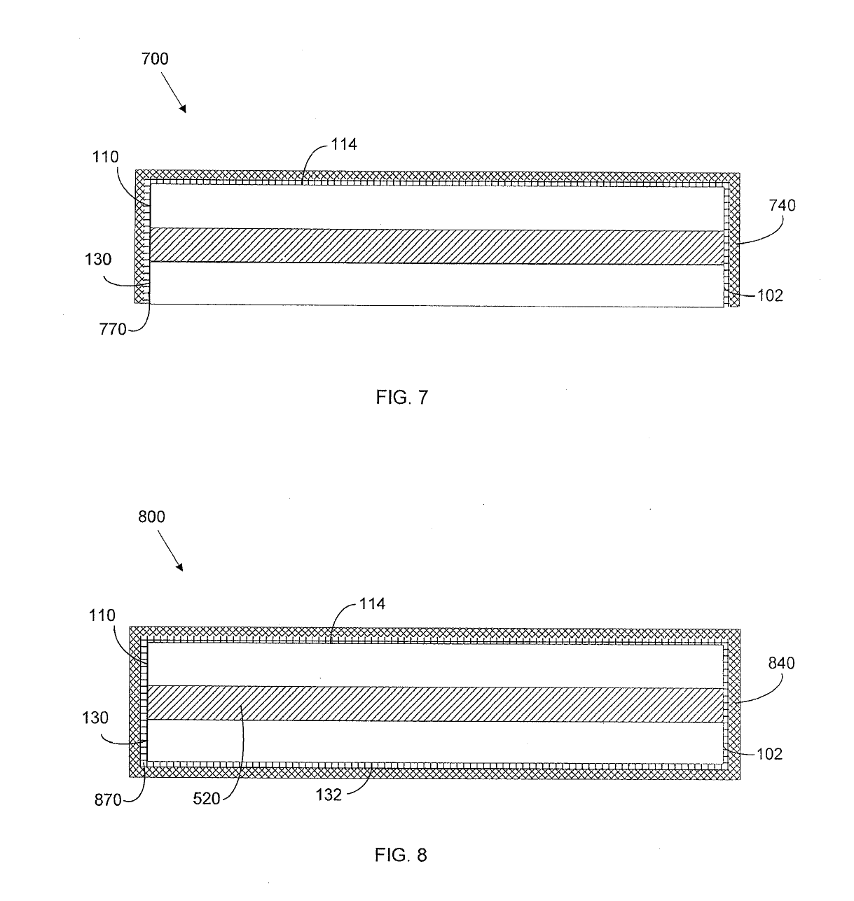

Module 700, shown in FIG. 7, illustrates another embodiment. In module 700, insulating seal 740 and material 770 extend across peripheral edge 102 of module 700 as well as extending across the entire front surface 114 of front support 110. FIG. 8 illustrates another embodiment in which module 800 has an insulating seal 840 and material 870 that extend across the across peripheral edge 102 of module 800 as well as extending across the entire front surface 114 of front support 110 and back surface 132 of back support 130. Thus, module 800 is entirely encased by insulating seal 840. In each of FIGS. 7 and 8, insulating seals 740, 840 are formed of an insulative material that is light transmissive and may be transparent or translucent to wavelengths of light generated by the sun. Also, in each of FIGS. 7 and 8, active material 520 extends to peripheral edge 102 of front and back supports 110, 130, but may extend by a range of 2 cm to 0 mm of peripheral edge 102 of module 700, 800. The corners of insulated seal 740 and 840 may also be rounded to act as a lens to redirect incident light to active material 520.

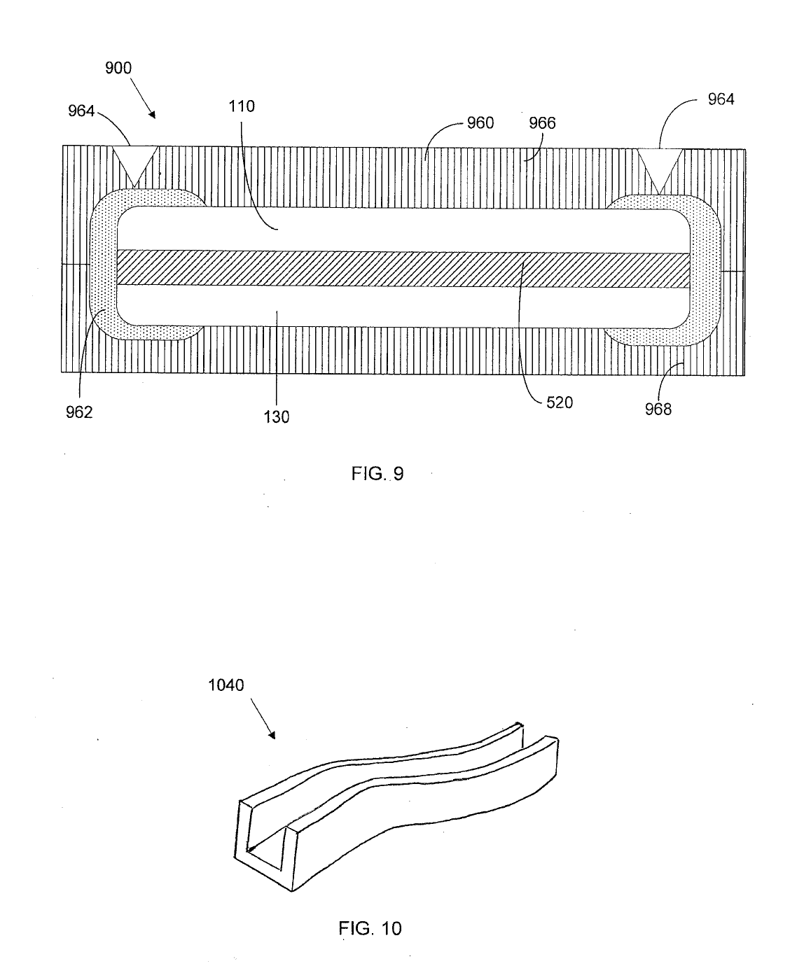

One method of forming an insulating seal by a molding operation and using a two part molding device 900 is shown in FIG. 9. Molding device 900 includes a mold 960 that has injection openings 964, front mold 966, and back mold 968. Mold 960 encompass a module that contains front support 110, active material 520, and back support 130 and has a cavity 962 that has interior profile shape of insulating seal 640. An insulating material injected into mold 960 through injectors openings 964 forms an insulating seal, here exemplified by seal 640 of FIG. 6. Once the insulating materials solidifies, mold 960 can be removed and insulating seal 640 is formed around front support 110, active material 520, and back support 130.

Although FIG. 9 illustrates a mold 900 for forming the FIG. 6 seal 640 without material 670, it may be adapted to mold any of the seals described and illustrated with respect to the embodiments described herein.

FIG. 10 illustrates an extruded insulating seal 1040. In this embodiment, extruded insulating seal 1040 is formed as a structure separate from the remainder of a solar module comprising of front and back supports and an active material. Extruded insulating seal 1040 may be a single piece that is wrapped around the entire periphery of the module, or it may be various discrete pieces that may be fastened together and fastened to the entire periphery of the module.

After manufacture, extruded insulating seal 1040 can be attached to the periphery of the solar module. Insulating seal 1040 may be clipped or pressed onto the solar module or an adhesive may be used to attach insulating seal 1040 to the solar module. Insulating seal 1040 may have curved edges and may be made of any insulative material. Additionally, insulating seal 1040 is light transmissive and may be made of a translucent or transparent material. Further, any of the seals described and illustrated with respect to the embodiments described herein may be extruded insulating seals that are separately formed and then attached to the peripheral edge of a module.

While embodiments have been described in detail, it should be readily understood that the invention is not limited to the disclosed embodiments. Rather the embodiments can be modified to incorporate any number of variations, alterations, substitutions, or equivalent arrangements not heretofore described without departing from the spirit and scope of the invention.

What is claimed as new and desired to be protected by Letters Patent of the United States is:

1. A solar module comprising:
a front support having a length and width;
a back support having a length and width substantially the same as the length and width of the front support, the back support being aligned with said front support and defining, with said front support, peripheral edges of the front and back supports;
an active photo sensitive material area provided between the front and back supports;
an electrically insulating light transmissive material located at least at the peripheral edges of the front and back supports between said front and back supports and between said active material and the peripheral edges of said front and back supports and which further extends to cover peripheral edges of said front and back supports .

2. The solar module of claim 1 wherein said electrically insulating light transmissive material has a T cross sectional shape.

3. The solar module of claim 1 wherein said electrically insulating light transmissive material extends across the entirety of a front surface of said front support.

4. The solar module of claim 3 wherein said electrically insulating light transmissive material extends across the entirety of a back surface of said back support.

5. The solar module of claim 1 wherein said electrically insulating light transmissive material comprises a sidewall and a pair of edges extending from said sidewall which respectively engage with a front surface of said front support and a back surface of said back support.

6. The solar module of claim 5 wherein said active material area extends to an area beneath extending edges of said seal which engage with said front surface of said front support.

7. The solar module of claim 5 wherein said sidewall and extending edges define, with the peripheral edges of said front and back supports, a cavity.

8. The solar module of claim 7 wherein said cavity is filled with one of the following: gas, air, sealant, silicone, polyisobutylene, or an insulative material.

9. The solar module of claim 5 wherein said extending edges of said electrically insulating light transmissive material which engage with said front surface of said front support have a rounded end profile to redirect an incident light beam towards said active material.

10. The solar module of claim 1 wherein peripheral edges of said front and back supports have rounded profiles to redirect an incident light beam towards said active material.

11. The solar module of claim 1 wherein said electrically insulating light transmissive material frames all peripheral edges of said front and back supports.

12. The solar module of claim 1 wherein said electrically insulating light transmissive material is transparent or translucent.

13. The solar module of claim 1 wherein said electrically insulating light transmissive material is formed of a polymer material.

14. The solar module of claim 13 wherein said polymer material is selected from a group comprising of polycarbonate, acrylic, silicone, and polyurethane.

15. The solar module of claim 1 wherein the active material extends to the peripheral edges of the front and back supports.

16. The solar module of claim 1 wherein the electrically insulating light transmissive material provides exterior surfaces which redirects an incident light beam towards said active material.

17. The solar module of claim 1 further comprising an additional material provided between the front and back supports and at least a portion of the electrically insulating light transmissive material.

18. The solar module of claim 17 wherein the additional material is a moisture barrier comprising a desiccant material.

19. The solar module of claim 18 wherein the desiccant material comprises polyisobutylene.

20. The solar module of claim 17 wherein the additional material comprises a primer.

21. The solar module of claim 17 wherein the additional material comprises an adhesive selected from a group consisting of organosilane and titanate.

22. The solar module of claim 1 wherein said electrically insulating material has a C cross section shape.
